(19) United States
(12) Patent Application Publication
(10) Pub. No.: US 2013/0048355 A1
(43) Pub. Date: Feb. 28, 2013

(54) PRINTED WIRING BOARD

(71) Applicants: Toru FURUTA, Ogaki-shi (JP); Hirofumi FUTAMURA, Ogaki-shi (JP); Hisashi MINOURA, Ogaki-shi (JP)

(72) Inventors: Toru FURUTA, Ogaki-shi (JP); Hirofumi FUTAMURA, Ogaki-shi (JP); Hisashi MINOURA, Ogaki-shi (JP)

(73) Assignee: IBIDEN Co., Ltd., Ogaki-shi (JP)

(21) Appl. No.: 13/537,885

(22) Filed: Jun. 29, 2012

Related U.S. Application Data
(60) Provisional application No. 61/528,838, filed on Aug. 30, 2011.

(51) Int. Cl. H05K 1/11; H05K 1/09; H05K 1/00

(52) U.S. Cl. 174/257; 174/258

(57) ABSTRACT

A printed wiring board has a core substrate including an insulative base material and having a penetrating hole, a first conductive circuit formed on a first surface of the substrate, a second conductive circuit formed on a second surface of the substrate, and a through-hole conductor including a copper-plated film and formed in the penetrating hole such that the through-hole conductor is connecting the first and second conductive circuits. The insulative base material of the substrate includes reinforcing material and resin and has a thermal expansion coefficient in a Z direction which is set at or above a thermal expansion coefficient of the copper-plated film of the through-hole conductor and set at or below 23 ppm, and the insulative base material of the substrate has a thermal expansion coefficient in an XY direction which is set lower than the thermal expansion coefficient of the copper-plated film of the through-hole conductor.

### CROSS-REFERENCE TO RELATED APPLICATIONS

The present application is based on and claims the benefit of priority to U.S. application No. 61/528,838, filed Aug. 30, 2011, the entire contents of which are incorporated herein by reference.

### BACKGROUND OF THE INVENTION

1. Field of the Invention

The present invention relates to a printed wiring board having a through-hole conductor.

2. Discussion of the Background

Japanese Laid-Open Patent Publication No. H11-260953 describes built-in stiffener in a substrate. As an example listed in Japanese Laid-Open Patent Publication No. H11-260953, the thermal expansion coefficient of the stiffener is set lower than that of the substrate. As a preferred example listed in Japanese Laid-Open Patent Publication No. H11-260953, the thermal expansion coefficient of the substrate is set to be equal to that of a semiconductor chip. The entire contents of this publication are incorporated herein by reference.

### SUMMARY OF THE INVENTION

According to one aspect of the present invention, a printed wiring board has a core substrate including an insulative base material and having a penetrating hole, a first conductive circuit formed on a first surface of the core substrate, a second conductive circuit formed on a second surface of the core substrate, and a through-hole conductor including a copper-plated film and formed in the penetrating hole such that the through-hole conductor is connecting the first conductive circuit and the second conductive circuit. The insulative base material of the core substrate includes a reinforcing material and a resin and has a thermal expansion coefficient in a Z direction which is set at or above a thermal expansion coefficient of the copper-plated film of the through-hole conductor and set at or below 23 ppm, and the insulative base material of the core substrate has a thermal expansion coefficient in an XY direction which is set lower than the thermal expansion coefficient of the copper-plated film of the through-hole conductor.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(A)-1(E) are views showing manufacturing steps of a printed wiring board according to a first embodiment of the present invention;

FIGS. 2(A)-2(C) are views showing manufacturing steps of a printed wiring board according to the first embodiment;

FIGS. 3(A)-3(B) are views showing manufacturing steps of a printed wiring board according to the first embodiment;

FIG. 4 is a cross-sectional view of a printed wiring board having solder bumps according to the first embodiment;

FIG. 5 is an applied example of a printed wiring board according to the first embodiment;

FIGS. 6(A)-6(D) are views illustrating stress exerted on a core substrate;

FIG. 7 is a cross sectional view of a printed wiring board according to a second embodiment;

FIGS. 8(A)-8(D) are views showing manufacturing steps of a printed wiring board according to the second embodiment;

FIGS. 9(A)-9(B) are microscopic photographs showing a boundary between a through-hole conductor and an insulative base material;

FIG. 10 is a cross-sectional view of a printed wiring board according to a third embodiment; and

FIGS. 11(A)-11(C) are views showing manufacturing steps of a printed wiring board according to the third embodiment.

### DETAILED DESCRIPTION OF THE EMBODIMENTS

The embodiments will now be described with reference to the accompanying drawings, wherein like reference numerals designate corresponding or identical elements throughout the various drawings.

### First Embodiment

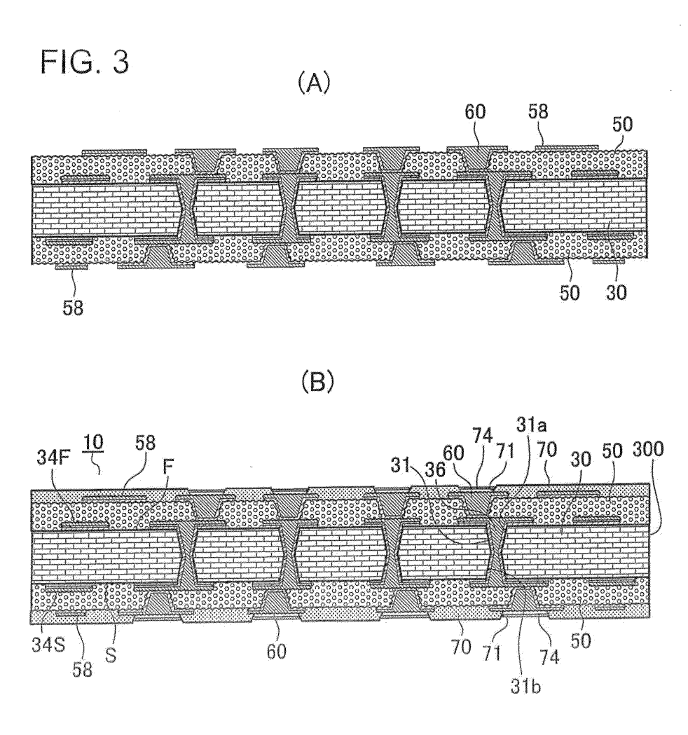

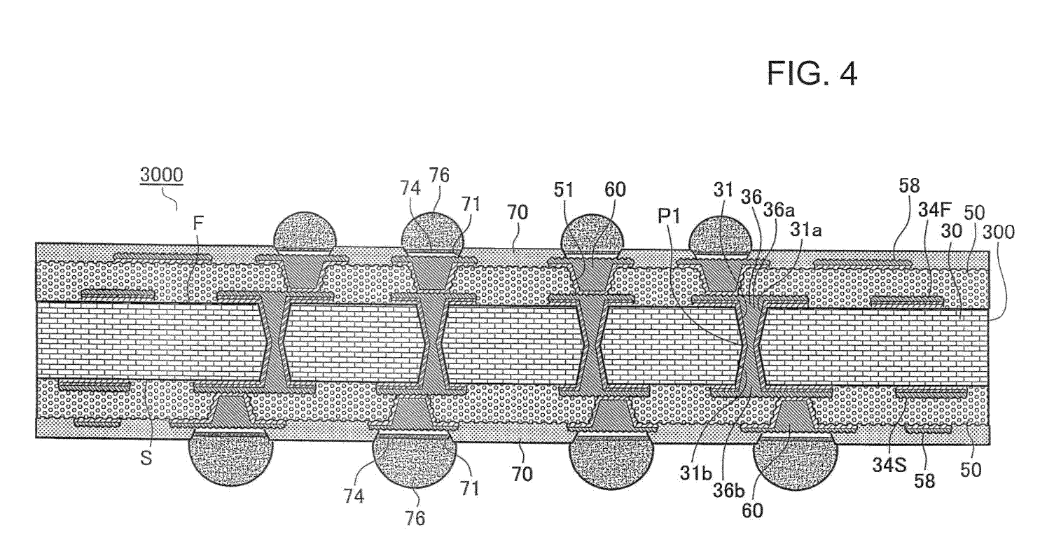

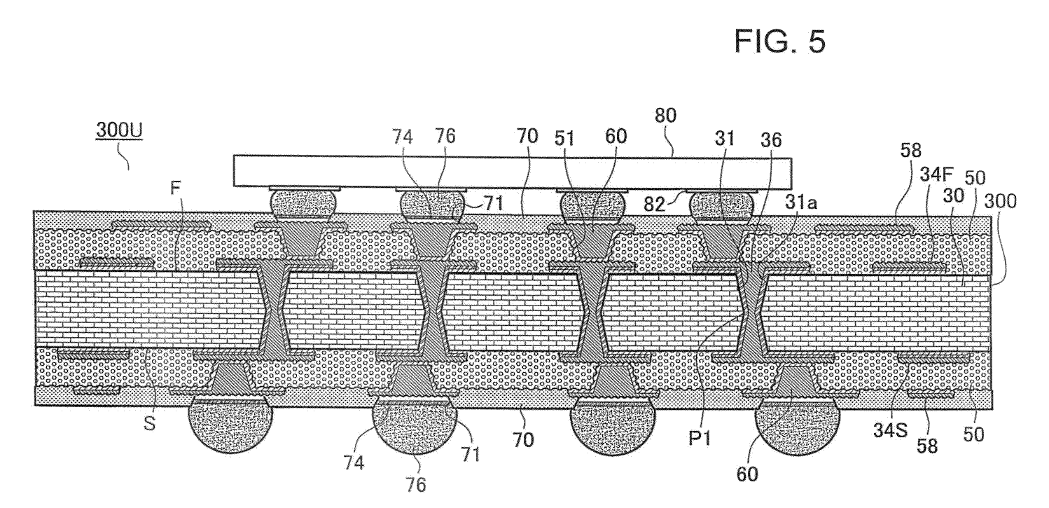

FIG. 3(B) shows a cross-sectional view of printed wiring board 10 according to a first embodiment. FIG. 5 is a usage example of the printed wiring board in FIG. 3(B), where IC chip 80 is mounted on printed wiring board 10. As shown in FIG. 3(B), printed wiring board 10 has core substrate 300, which is formed with insulative base material 30 having penetrating hole 31, conductive layers (34F, 34S) formed on the upper and lower surfaces of the insulative base material, and through-hole conductor 36 formed in a penetrating hole and connecting conductive layer (34F) and conductive layer (34S). A through-hole conductor is made of copper-plated film. Conductive layers (34F, 34S) include lands of through-hole conductors. The insulative base material has first surface (F) and second surface (S) opposite the first surface. Conductive circuit (34F) formed on first surface (F) is a first conductive circuit, and conductive circuit (34S) formed on second surface (S) is a second conductive circuit. A penetrating hole is made up of a first opening (31a) narrowing from first surface (F) toward second surface (S) and of second opening (31b) narrowing from second surface (S) toward first surface (F). Then, a through-hole conductor is formed in penetrating hole 31. In FIG. 4, penetrating hole 31 is filled with copper-plated film. Through-hole conductor 36 is made up of first conductor portion (36a) tapering from first surface (F) toward second surface (S) and of second conductor portion (36b) tapering from second surface (S) toward first surface (F). Buildup layers are formed on both surfaces of core substrate 30. A buildup layer includes resin insulation layer 50, conductive layer 58 on the resin insulation layer, and via conductor 60 which penetrates through resin insulation layer 50 and connects different conductive layers. Conductive layer 58 includes a conductive circuit and a via-conductor land. Solder-resist layer 70 is formed on resin insulation layer 50 and conductive layer 58, having an opening to expose conductive layer 58. Solder bumps (76, 76) are formed on conductive layers exposed through the openings of the solder-resist layers. As shown in FIG. 5, IC chip 80 is mounted on printed wiring board 10 through upper-surface side solder bump 76.

The insulative base material of the first embodiment is formed with reinforcing material, resin and the like. The reinforcing material is glass cloth or aramid fiber. The material of the glass for the glass cloth is S-glass or E-glass. S-glass is preferred, since a small amount of such glass can lower the thermal expansion coefficient of the insulative base material. This enhances the process of forming penetrating holes. The insulative base material may further include inorganic particles. Silica particles and alumina particles are examples of inorganic particles. In the first embodiment, the thermal expansion coefficient (CTE) of the insulative base material is adjusted by selecting types of reinforcing material and inorganic particles and by adjusting the amounts of reinforcing material and inorganic particles. The CTE of the insulative base material in direction Z is adjusted to be between the CTE value of the copper-plated film forming through-hole conductors and 23 ppm. The CTE of the insulative base material in direction X-Y is adjusted to be a value lower than that of the copper-plated film forming through-hole conductors. The amount of inorganic particles is 20 wt. % to 60 wt. %. The CTE of the copper-plated film is approximately 17 ppm. Here, direction X-Y is the direction parallel to the first surface of the insulative base material, and direction Z is the direction perpendicular to the first surface of the insulative base material. The insulative base material is manufactured by impregnating reinforcing material with resin, and then by curing the resin.

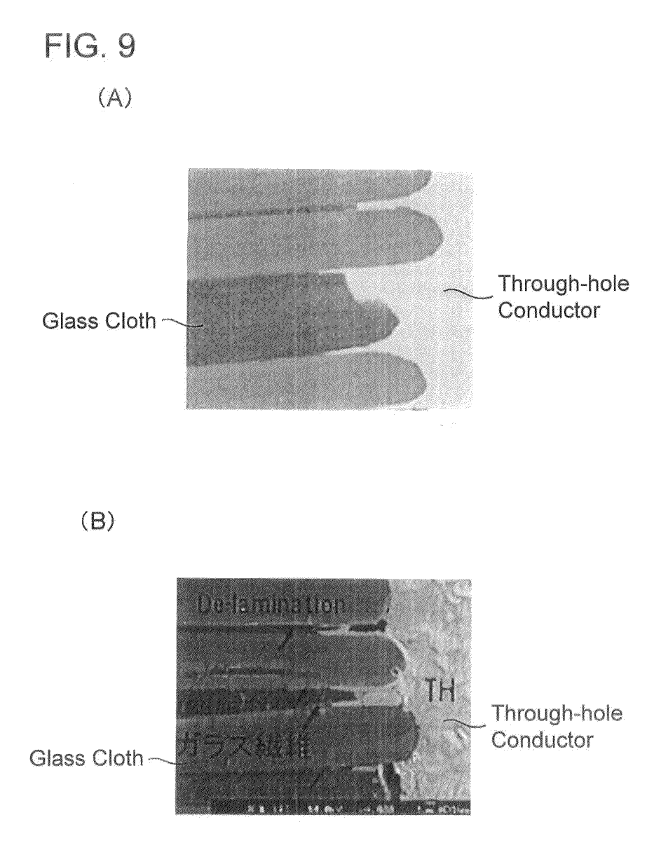

FIG. 9 shows a portion of the core substrate in a reference example. The glass cloth of the insulative base material in the reference example is formed with glass fiber made of S-glass. Then, by adjusting the amount of silica particles, the CTE of the insulative base material in direction X-Y of the reference example is adjusted to be approximately 5 ppm and the CTE in direction Z to be approximately 12 ppm. FIG. 9(A) shows part of the core substrate prior to evaluation testing. Glass cloth is shown on the left side of FIG. 9(A), and a through-hole conductor is shown on the right side. Each glass fiber is adhered by resin.

Heat-cycle testing is conducted on a printed wiring board having the core substrate shown in FIG. 9(A). The printed wiring board is kept at −55 degrees for 3 minutes, and then at 125 degrees for 3 minutes, which are set as one cycle. FIG. 9(B) shows the portion of the core substrate after 1000 cycles. The glass cloth is shown on the left side of FIG. 9(B), and the through-hole conductor is shown on the right side. In FIG. 9(B), space is observed between glass fibers. Delamination has occurred in the insulative base material. If space exists between glass fibers, it is thought that the copper in the through-hole conductors migrates to the space, causing a decrease in insulation resistance between through-hole conductors. In addition, it is thought that cracking caused by delamination in the insulative base material occurs in through-hole conductors.

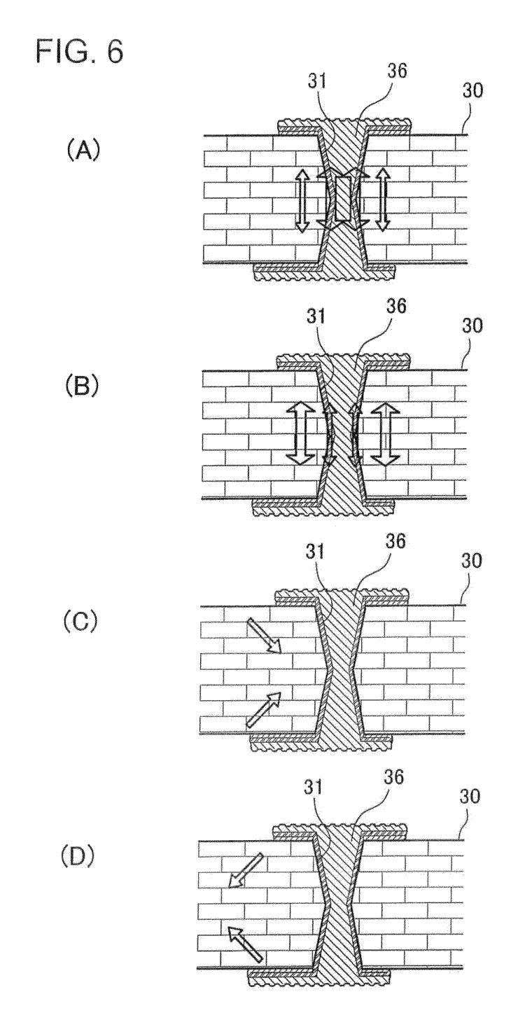

FIG. 6 schematically shows CTE values of insulative base materials and through-hole conductors. The level of a CTE value is indicated by the width of an arrow. FIG. 6(A) shows the CTE of a through-hole conductor and the CTE of an insulative base material in a reference example. In the reference example, the CTE value of the conductor that forms through-hole conductors is higher than the CTE value of the insulative base material in direction Z. In addition, the CTE value of the conductor that forms through-hole conductors is higher than the CTE value of the insulative base material in direction XY. Therefore, when the temperature of the core substrate rises, it is thought that the insulative base material is pulled by through-hole conductors, because the stretching of through-hole conductors in direction Z is greater than the stretching of the insulative base material in direction Z. Accordingly, force to delaminate each glass fiber (reinforcing fiber) is thought to be exerted on glass cloth. Namely, tensile stress is thought to be exerted on glass cloth in the reference example. Such tensile stress is thought to cause delamination of glass cloth as shown in FIG. 9(B).

FIG. 6(B) shows the CTE of a through-hole conductor and the CTE of an insulative base material in a printed wiring board of the first embodiment. In the first embodiment, the CTE value of the insulative base material in direction Z is set at or above the CTE value of the conductor that forms through-hole conductors. Therefore, when the temperature of the core substrate rises, the stretching of the insulative base material in direction Z is equal to or greater than the stretching of through-hole conductors in direction Z. Accordingly, it is thought that through-hole conductors suppress the stretching of the insulative base material in direction Z. Namely, it is thought that the insulative base material receives compressive force in direction Z from through-hole conductors. Since reinforcing material such as glass cloth receives compressive force, it is thought that delamination seldom occurs in the reinforcing material. Also, in the first embodiment, the CTE value of the insulative base material in direction XY is lower than the CTE value of the conductor that forms through-hole conductors. Therefore, when the temperature of the core substrate rises, the stretching of the insulative base material in direction XY is smaller than the stretching of through-hole conductors in direction XY. Through-hole conductors are thought to press the side walls of penetrating holes.

FIG. 6(D) shows the directions of forces exerted on the insulative base material when the temperature rises in a printed wiring board of the first embodiment. The directions shown in FIG. 6(D) are thought to be the directions obtained considering the CTE values of the insulative base material and through-hole conductors. It is thought that the force in direction Z is compressive and the force in direction XY is also compressive. Usually, it is thought that resin is more likely to be damaged by tensile force than by compressive force. The amount of resin existing between reinforcing fibers (reinforcing material) is small. However, since compressive force is exerted on the insulative base material in the first embodiment, it is thought that cracking or the like is unlikely to occur in resin between reinforcing fibers. Therefore, it is thought that delamination is unlikely to occur between reinforcing fibers. Accordingly, insulation reliability between through-hole conductors is high in the first embodiment, leading to high connection reliability of through-hole conductors.

Also, since through-hole conductors press the side walls of penetrating holes at high temperatures in the first embodiment, it is thought that through-hole conductors seldom delaminate from the inner walls of penetrating holes. When the temperature of the printed wiring board rises, since through-hole conductors are adhered to penetrating holes, it is thought that through-hole conductors cause the insulative base material to receive compressive force in direction Z. Accordingly, it is thought that delamination is unlikely to occur between glass fibers in the first embodiment. Therefore, insulation reliability between through-hole conductors is high. Also, since delamination seldom occurs in the insulative base material, cracking seldom occurs in through-hole conductors.

FIG. 6(C) shows an example where the CTE of an insulative base material in direction Z is higher than the CTE of a through-hole conductor, and the CTE of the insulative base material in direction XY is higher than the CTE of the through-hole conductor. When the temperature of a printed wiring board rises, directions of force exerted on the insulative base material are shown in FIG. 6(C). The directions shown in FIG. 6(C) are thought to be the directions obtained considering the CTE values of the insulative base material and through-hole conductors. Since the insulative base material stretches more in direction XY than through-hole conductors, it is thought that through-hole conductors are pressed by insulative base material. It is thought that the force in direction Z is compressive and the force in direction XY is tensile. Usually, it is thought that resin is more likely to be damaged by tensile force than by compressive force. Since the amount of resin existing between reinforcing fibers is small, cracking or the like is thought to occur in the resin between reinforcing fibers when tensile force is exerted on the insulative base material, causing delamination between reinforcing fibers. Glass fibers or aramid fibers in glass cloth are examples of reinforcing fibers. Also, as shown in FIG. 5, when a through-hole conductor has bent portion (P1), the force in FIG. 6(C) is thought to be concentrated in bent portion (P1). In such a case, it is thought that through-hole conductors tend to be damaged.

Through-hole conductor 36 in FIG. 5 has first conductor portion (36a) tapering from the first surface toward the second surface and second conductor portion (36b) tapering from the second surface toward the first surface. Since the side walls of penetrating holes for such through-hole conductors are slanted, when the temperature of a printed wiring board rises, the through-hole conductors of the first embodiment can suppress the stretching of the insulative base material in direction Z more efficiently than through-hole conductors formed in straight penetrating holes. Therefore, according to a printed wiring board having through-hole conductors, which are made up of first conductor portion (36a) tapering from the first surface toward the second surface and of second conductor portion (36b) tapering from the second surface toward the first surface, delamination seldom occurs between reinforcing fibers such as glass fibers.

In a printed wiring board of the first embodiment, through-hole conductor 36 has a bent portion at connected portion (P1) between first opening (31a) and second opening 31b). Since stress tends to concentrate in such a bent portion, through-hole conductors in the first embodiment tend to be damaged. If delamination occurs in the insulative base material, it is thought that the amount of deformation of the insulative base material increases. In such a case, it is thought that stress exerted on bent portions of through-hole conductors increases. However, as described above, since delamination is suppressed between the resin and reinforcing fibers of the insulative base material, through-hole conductors are seldom damaged in a printed wiring board of the first embodiment. Even when through-hole conductors have bent portions, connection reliability of the through-hole conductors is enhanced in the first embodiment. The CTE value of copper-plated film is approximately 17 ppm. In each embodiment, the CTE value of the insulative base material in direction Z is set at 23 ppm or lower. When the CTE value in direction Z exceeds 23 ppm, the difference in CTE values in direction Z increases between through-hole conductors and insulative base material. Accordingly, cracking tends to occur in through-hole conductors. Especially in a printed wiring board having through-hole conductors with bent portions, damage is prevented in through-hole conductors if the CTE value in direction Z is set at 23 ppm or lower.

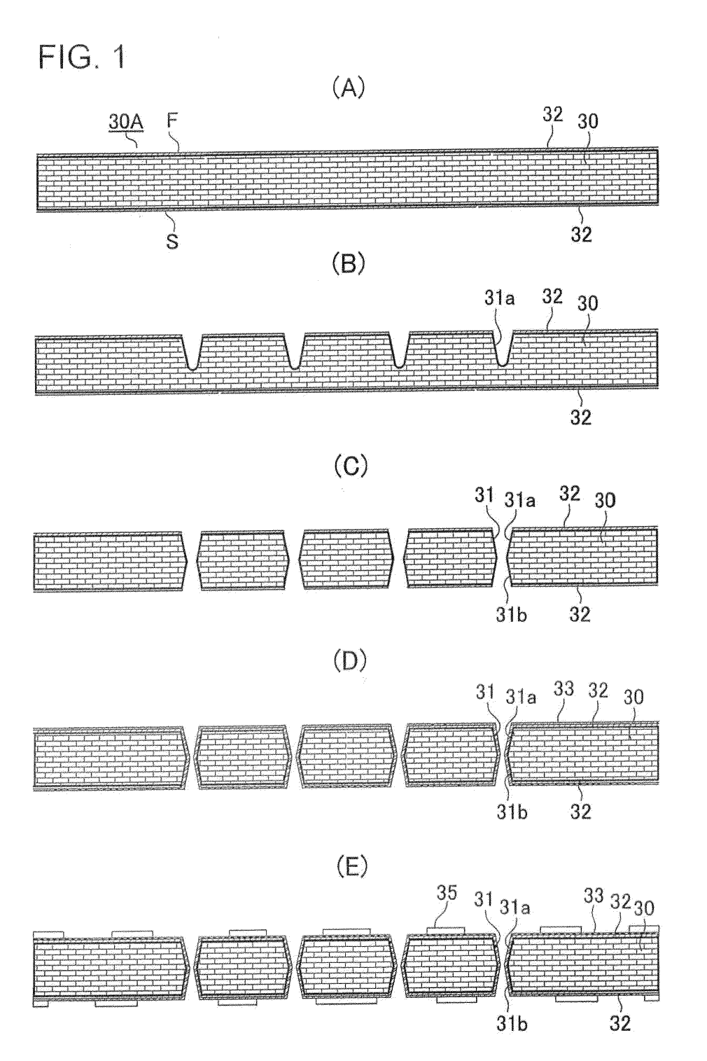

A method for manufacturing printed wiring board 10 is shown in FIGS. 1-4.

(1) Copper-clad laminate (30A) is prepared, being formed with insulative base material 30 having first surface (F) and second surface (S) opposite the first surface and with copper foils 32 laminated on both surfaces of the insulative base material (FIG. 1(A)). Insulative base material 30 includes resin such as epoxy, reinforcing material such as glass cloth made of S-glass, and inorganic particles such as silica and alumina. When insulative base material is formed with reinforcing material, inorganic particles and resin, the amount of reinforcing material is 30-70 wt. %, and the amount of inorganic particles is 10-50 wt. %. The average particle diameter of inorganic particles is 0.1-1 μm. In so setting, the thermal expansion coefficient (CTE) of the insulative base material in direction Z is adjusted to be approximately 17˜23 ppm, and the thermal expansion coefficient (CTE) in direction X-Y is adjusted to be lower than 17 ppm. Those CTE values are al (i.e., below Tg). The thickness of the insulative base material is 0.1 mm to 0.25 mm. The thickness of copper foil 32 is 3˜5 μm. First, a laser is irradiated at copper-clad laminate (30A) from the first-surface (F) side, and first openings (31a) tapering from the first surface toward the second surface are formed at positions for forming through-hole conductors (FIG. 1(B)). Then, a laser is irradiated at copper-clad laminate (30A) from the second-surface (S) side, and second openings (31b) tapering from the second surface toward the first surface are formed at positions for forming through-hole conductors. First openings (31a) and second openings (31b) are joined to form penetrating holes in insulative base material 30 (FIG. 1(C)). Tapering includes situations in which openings (31a, 31b) gradually narrow toward the center of the core substrate in a cross-sectional direction.

(2) Electroless copper-plated film 33 with a thickness of 0.6 μm is formed on the side walls of penetrating holes and on copper foils 32 (FIG. 1(D)).

(3) Plating resist 35 is formed on electroless plated film 33 (FIG. 1(E)).

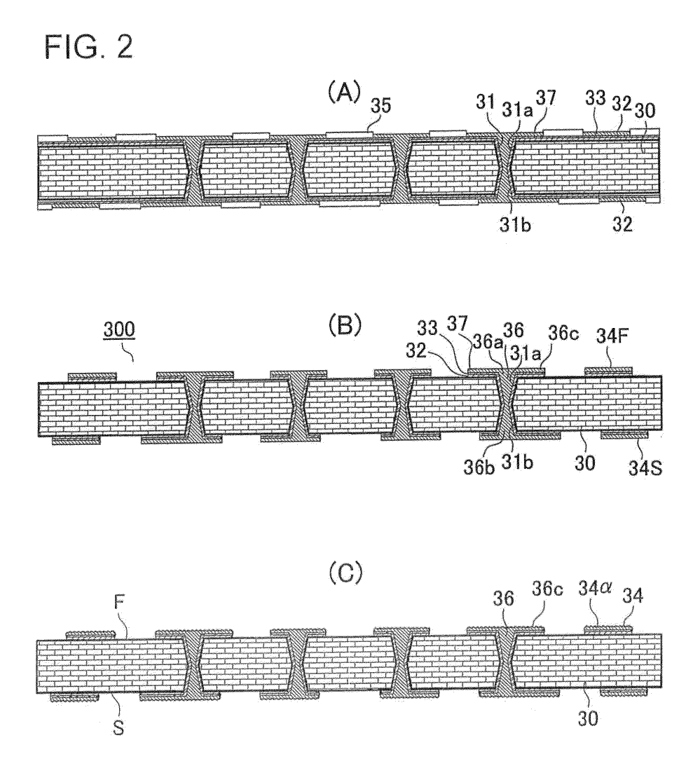

(4) Electrolytic copper-plated film 37 is formed in penetrating holes 31 and on electroless plated film 33 exposed from plating resist 35 (FIG. 2(A)). Penetrating holes 31 are filled with electrolytic plated film 37.

(5) Plating resist 35 is removed by 5% KOH. Then, electroless plated film 33 and copper foil 32 between portions of electrolytic plated film 37 are removed by an etching solution mainly containing copper (II) chloride. Through-hole conductors 36 and conductive layers (34F, 34S) including through-hole lands (36c) are formed. Core substrate 300 is completed (FIG. 2(B)).

(6) Roughened surfaces (34a) (concavo-convex layers) are formed on conductive layers 34 (FIG. 2(C)).

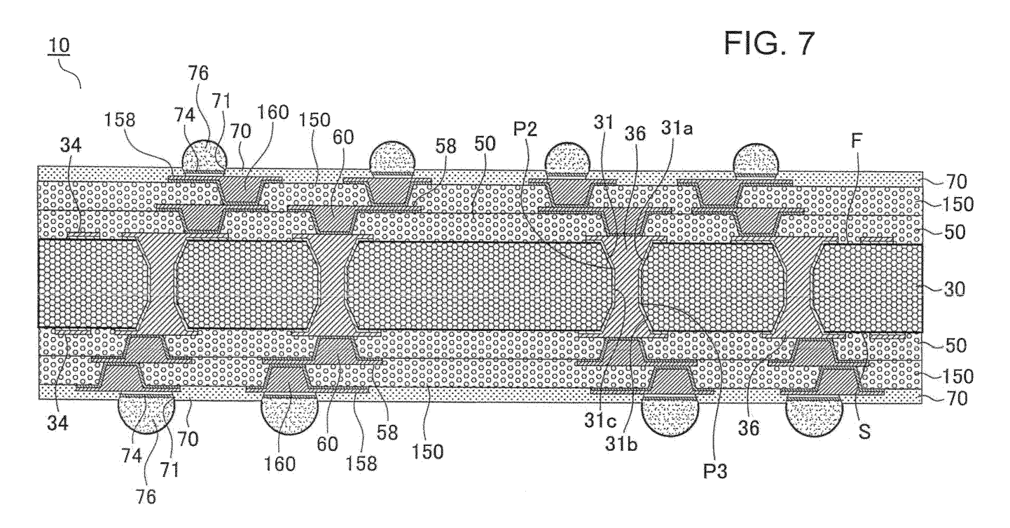

Buildup layers are formed on both surfaces of core substrate 300. The first surface of the core substrate corresponds to the first surface of the insulative base material, and the second surface of the core substrate corresponds to the second surface of the insulative base material. Buildup layers are formed by a semi-additive method. Methods for forming buildup layers are described in “Easy to Understand Process for Forming Buildup Multilayer Wiring Board” (published by Nikkan Kogyo Shimbun, Ltd., author: Kiyoshi Takagi) and the entire contents of this publication are incorporated herein by reference. In FIG. 3(A), one-layer buildup layers are formed on the core substrate. A one-layer buildup layer includes one layer of resin insulation layer 50, conductive layer 58 on the resin insulation layer, and via conductors 60 which penetrate through the resin insulation layer and connect different conductive layers. FIG. 7 shows an example where two-layer buildup layers are formed on the core substrate.

Next, solder-resist layers 70 having openings 71 are formed (FIG. 3(B)). Metal films (71, 74) are formed on conductive circuits (pads) exposed through openings 71. Metal film 71 is made of nickel, and metal film 74 is made of gold. Printed wiring board 10 is completed. Solder bumps 76 are formed on the metal films. Printed wiring board 3000 with solder bumps is completed (FIG. 4).

### Second Embodiment

FIG. 7 shows a cross-sectional view of printed wiring board 10 according to a second embodiment. The shape of penetrating holes 31 for through-hole conductors and the number of layers of buildup layers in the second embodiment are different from those in the first embodiment. The rest of the second embodiment is the same as the first embodiment, and the insulative base material of the second embodiment is the same as that of the first embodiment.

Penetrating hole 31 of the second embodiment is made up of first opening (31a) tapering from first surface (F) toward second surface (S), of second opening (31b) tapering from second surface (S) toward first surface (F), and of third opening (31c) in substantially a straight shape and connecting the first opening and the second opening.

In a printed wiring board of the second embodiment, the shape of penetrating holes 31 is more complex than the shape of penetrating holes 31 in the first embodiment. Thus, the contact area between through-hole conductors and the side walls of the penetrating holes increases. When the temperature of the printed wiring board rises, the insulative base material is compressed in direction Z by through-hole conductors. In addition, since the bent portions of through-hole conductors increase, stress is dispersed. Through-hole conductors are seldom damaged.

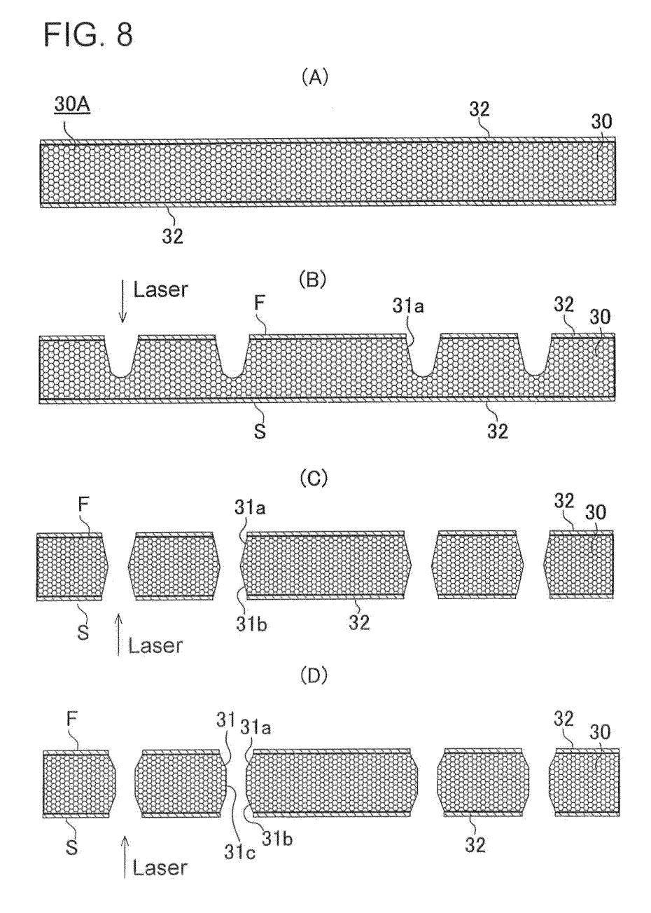

FIG. 8 shows a method for manufacturing a core substrate of the second embodiment.

(1) The same as in the first embodiment, copper-clad laminate (30A) is prepared, where 3˜5 μm copper foils 32 are laminated on both surfaces of insulative base material 30 (FIG. 8(A)).

(2) A CO2 laser is irradiated on first surface (F) of copper-clad laminate (30A), and first openings (31a) to form penetrating holes for through-hole conductors are formed on the first-surface (F) side of insulative base material 30 (FIG. 8(B)). First openings (31a) taper from first surface (F) toward second surface (S).

(3) A CO2 laser is irradiated on second surface (S) of copper-clad laminate (30A), and second openings (31b) to form penetrating holes for through-hole conductors are formed on the second-surface (S) side of insulative base material 30 (FIG. 8(C)). Second openings (31b) taper from second surface (S) toward first surface (F).

(4) A CO2 laser is irradiated into second openings (31b) from the second-surface (S) side of copper-clad laminate (30A), and third openings (31c) connecting first openings (31a) and second openings (31b) are formed (FIG. 8(D)). Third openings (31c) are shaped substantially straight. A core substrate is formed by employing the same method as that in the first embodiment in subsequent procedures. Then, buildup layers are formed by a method the same as in the first embodiment.

The CTE of through-hole conductors and the CTE of the insulative base material in the second embodiment have the same relationship as that in the first embodiment. Therefore, it is thought that the second embodiment has the same effects from the same causes as those in the first embodiment.

### Third Embodiment

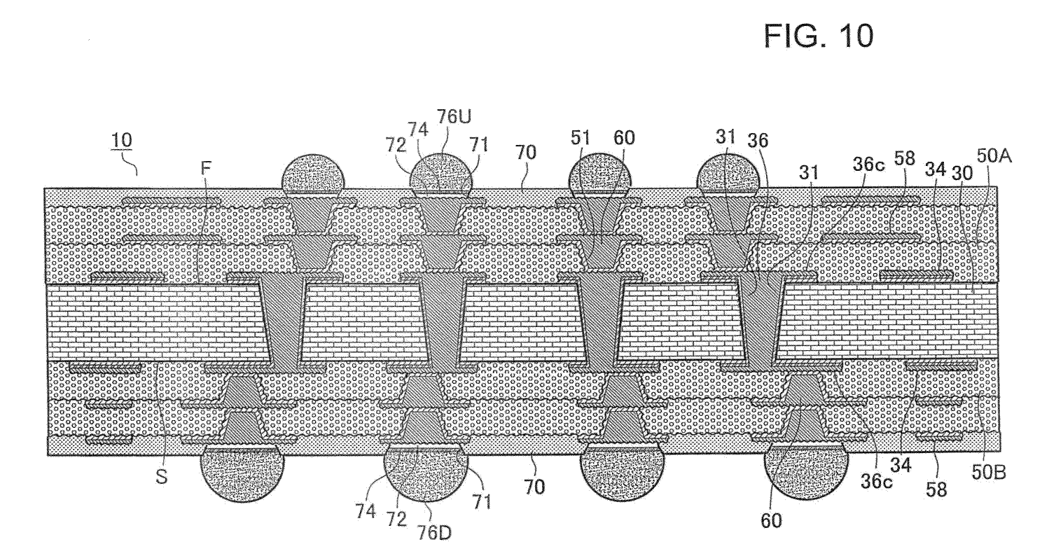

FIG. 10 shows a cross-sectional view of printed wiring board 10 according to a third embodiment. The shape of penetrating holes 31 for through-hole conductors in the third embodiment is different from that in the second embodiment. The rest of the third embodiment is the same as that in the second embodiment, and the insulative base material of the third embodiment is the same as that in the first embodiment. Penetrating holes 31 in the third embodiment taper from first surface (F) toward second surface (S).

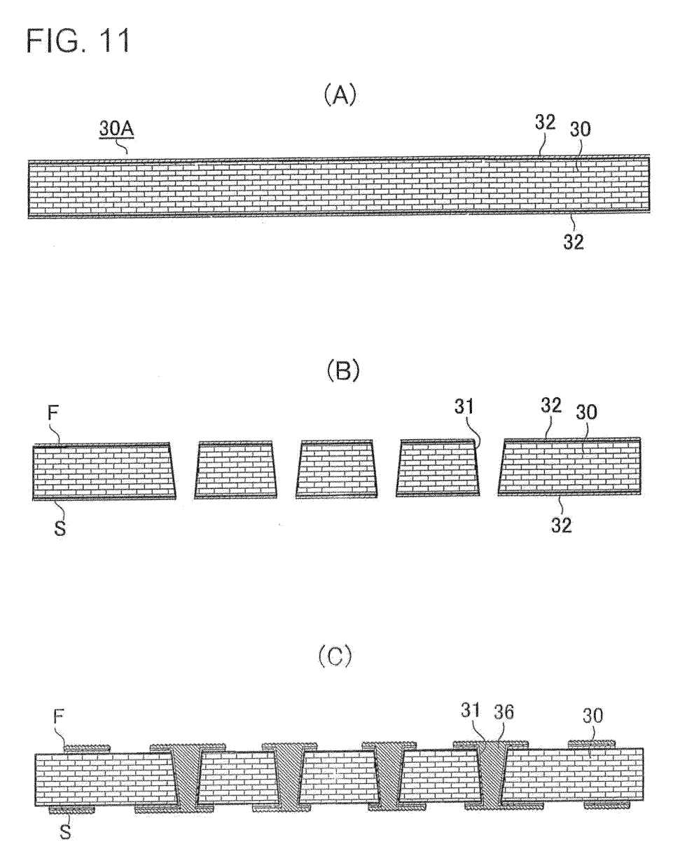

FIG. 11 shows a method for manufacturing a core substrate of the third embodiment. The same as in the first embodiment, copper-clad laminate (30A) is prepared, where 3˜5 μm copper foils 32 are laminated on both surfaces of insulative substrate 30 (FIG. 11(A)).

A CO2 laser is irradiated on first surface (F) of copper-clad laminate (30A) to form penetrating holes tapering from first surface (F) of insulative base material 30 toward the second surface (FIG. 11(B)). A core substrate is formed by employing the same method as that in the first embodiment in the subsequent procedures (FIG. 11(C)). Then, buildup layers are formed by a method the same as in the first embodiment.

The CTE of through-hole conductors and the CTE of the insulative base material in the third embodiment have the same relationship as that in the first embodiment. Therefore, it is thought that the third embodiment has the same effects from the same causes as those in the first embodiment. Since through-hole conductors of the third embodiment do not have bent portions (P1), the reliability of through-hole conductors is thought to be higher than that in the first embodiment and the second embodiment. Also, since the shapes of penetrating holes in the first and second embodiments are more complex than the shape of penetrating holes in the third embodiment, it is thought that delamination seldom occurs in the insulative base material in the first and second embodiments.

In each embodiment, the thickness of the insulative base material is preferred to be 100 μm to 250 μm. If the thickness of the insulative base material increases, when the insulative base material stretches, the force to be exerted on through-hole conductors increases. If the thickness of the insulative base material exceeds 250 μm, cracking tends to occur in through-hole conductors. Especially, since through-hole conductors in the first and second embodiments have bent portions, they are prone to the above impact. If the thickness of the insulative base material decreases, compressive force exerted on the insulative base material is thought to decrease due to the difference in CTE values. If the thickness of the insulative base material is less than 100 μm, it is thought that force to prevent delamination of reinforcing fibers decreases. When the thickness of the insulative base material is 100 μm to 250 μm, it is thought that delamination in the insulative base material and damage to through-hole conductors are prevented.

In each embodiment, the thermal expansion coefficient of the insulative base material in direction XY is preferred to be 2 ppm or higher and 15 ppm or lower. The insulative base material receives compressive force at high temperatures, and thus delamination seldom occurs in reinforcing material. If the CTE in direction XY exceeds 15 ppm, the compressive force exerted on the insulative base material decreases, and if it is lower than 2 ppm, the compressive force increases. Accordingly, delamination tends to occur in the insulative base material, and causes damage to through-hole conductors. Especially, since through-hole conductors in the first and second embodiments have bent portions, such defects tend to occur. When the CTE ranges described above (direction Z, direction XY) are employed in printed wiring boards according to the first and second embodiments, such defects seldom occur in the printed wiring boards. Such defects include lowered insulation resistance of adjacent through-hole conductors.

### EXAMPLE 1

Varnish is manufactured by dispersing 0.3 μm silica particles in liquid cyanate resin. Glass cloth made of E-glass (reinforcing material) is impregnated with the varnish. An intermediate is obtained. Prepreg is obtained by drying the intermediate at 120 degrees for 5 minutes. The prepreg is sandwiched by 3 μm-thick copper foils, and the copper foils and prepreg are thermally pressed. The resin in the prepreg is cured and a copper-clad laminate is obtained (FIG. 1(A)). At the same time, 150 μm-thick insulative base material 30 is obtained from the prepreg. Insulative base material 30 has a first surface and a second surface. The amount of glass cloth contained in the insulative base material is approximately 50 wt. %, and the amount of inorganic particles is approximately 20 wt. %. The CTE value of the insulative base material in direction XY is approximately 12 ppm, and the CTE in direction Z is approximately 23 ppm. Both CTE values are α1. CTE values are measured by a thermomechanical analysis in compliance with JIS C 6481.

A CO2 laser is irradiated from the first-surface side of the insulative base material to form first openings (31a) on the first-surface side of the insulative base material (FIG. 1(B)). From the second-surface side of the insulative base material, a CO2 laser is irradiated at positions facing first openings (31a) to form second openings (31b) on the second-surface side of the insulative base material. Penetrating holes 31 are formed in the insulative base material (FIG. 1(C)).

Electroless copper-plated film 33 with a thickness of 0.6 μm is formed on the side walls of penetrating holes 31 and on copper foils 32 (FIG. 1(D)). Plating resist 35 is formed on electroless plated film 33 (FIG. 1(E)).

Electrolytic copper-plated film 37 is formed in penetrating holes 31 and on electroless plated film 33 exposed from plating resist 35 (FIG. 2(A)). Penetrating holes 31 are filled with electrolytic copper-plated film 37.

Plating resist 35 is removed by 5% KOH. Then, electroless plated film 33 and copper foil 32 between portions of electrolytic plated film 37 are removed by an etching solution mainly containing copper (II) chloride. Through-hole conductors 36 and conductive layers 34 including through-hole lands (36c) are formed. Core substrate 300 is completed (FIG. 2(B)).

One-layer buildup layers are formed by a semi-additive method on first surface (F) and second surface (S) of core substrate 300 (FIG. 3(A)).

Next, solder-resist layers 70 having openings 71 are formed on buildup layers

(FIG. 3(B)). Metal films (71, 74) are formed on conductive circuits (pads) exposed through openings 71. Metal film 71 is made of nickel and metal film 74 is made of gold. Printed wiring board 10 is completed. Solder bumps 76 are formed on the metal film. A printed wiring board with solder bumps is completed (FIG. 4).

### EXAMPLE 2

In Example 2, glass cloth made of S-glass is used as reinforcing material. The rest of Example 2 is the same as Example 1. In Example 2, the CTE value of the insulative base material in direction XY is approximately 5 ppm, and the CTE in direction Z is approximately 20 ppm. Both CTE values are α1.

### EXAMPLE 3

In Example 3, the amount of inorganic particles is changed from that in Example 2. The amount of inorganic particles in example 3 is approximately 25 wt. %. The rest of Example 3 is the same as Example 2. In example 3, the CTE value of the insulative base material in direction XY is approximately 3 ppm, and the CTE in direction Z is approximately 17 ppm. Both CTE values are α1.

### Reference Example 1

In Reference Example 1, the amount of reinforcing material is changed from that in Example 2. The amount of reinforcing material in Reference Example 1 is approximately 55 wt. %. The rest of Reference Example 1 is the same as Example 2. In Reference Example 1, the CTE value of the insulative base material in direction XY is approximately 1.5 ppm, and the CTE in direction X is approximately 14 ppm. Both CTE values are al. Heat-cycle testing described above is conducted on printed wiring boards in Example 1, Example 2, Example 3 and Reference Example 1, and the following are the results.

Delamination does not occur in glass cloth in Example 1, Example 2 and Example 3, but delamination does occur in glass cloth in Reference Example 1, because in the examples, CTE values of insulative base materials in direction XY are set lower than the CTE value of copper-plated film, and CTE values of insulative base materials in direction Z are set at or above the CTE value of copper-plated film. By contrast, in Reference Example 1, the CTE value of the insulative base material in direction Z is set lower than the CTE value of copper-plated film.

A printed wiring board according to an embodiment of the present invention has an insulative base material which is made of a reinforcing material and resin and has a first surface and a second surface opposite the first surface as well as a penetrating hole; a first conductive circuit formed on the first surface of the insulative base material; a second conductive circuit formed on the second surface of the insulative base material; and a through-hole conductor made of copper plating in the penetrating hole and connecting the first conductive circuit and the second conductive circuit. The thermal expansion coefficient of the insulative base material in direction Z is set at or above the thermal expansion coefficient of the copper-plated film forming the through-hole conductor and at or below 23 ppm. In addition, the thermal expansion coefficient of the insulative base material in direction XY is set lower than the thermal expansion coefficient of the copper-plated film forming the through-hole conductor.

Obviously, numerous modifications and variations of the present invention are possible in light of the above teachings. It is therefore to be understood that within the scope of the appended claims, the invention may be practiced otherwise than as specifically described herein.

What is claimed is:

1. A printed wiring board, comprising:
a core substrate comprising an insulative base material and having a penetrating hole;
a first conductive circuit formed on a first surface of the core substrate;
a second conductive circuit formed on a second surface of the core substrate; and
a through-hole conductor comprising a copper-plated film and formed in the penetrating hole such that the through-hole conductor is connecting the first conductive circuit and the second conductive circuit,
wherein the insulative base material of the core substrate includes a reinforcing material and a resin and has a thermal expansion coefficient in a Z direction which is set at or above a thermal expansion coefficient of the copper-plated film of the through-hole conductor and set at or below 23 ppm, and the insulative base material of the core substrate has a thermal expansion coefficient in an XY direction which is set lower than the thermal expansion coefficient of the copper-plated film of the through-hole conductor.

2. The printed wiring board according to claim 1, wherein the copper-plated film is formed in the penetrating hole such that the penetrating hole is filled and closed by the copper-plated film.

3. The printed wiring board according to claim 1, wherein the penetrating hole has a first opening portion narrowing from the first surface of the core substrate toward the second surface of the core substrate and a second opening portion narrowing from the second surface of the core substrate toward the first surface of the core substrate.

4. The printed wiring board according to claim 1, wherein the penetrating hole has a first opening portion narrowing from the first surface of the core substrate toward the second surface of the core substrate, a second opening portion narrowing from the second surface of the core substrate toward the first surface of the core substrate, and a third opening portion having a substantially straight shape and connecting the first opening portion and the second opening portion.

5. The printed wiring board according to claim 1, wherein the thermal expansion coefficient in the Z direction is a value of α1.

6. The printed wiring board according to claim 5, wherein the thermal expansion coefficient in the Z direction is set at 17 ppm or higher.

7. The printed wiring board according to claim 5, wherein the thermal expansion coefficient in the XY direction is a value of α1.

8. The printed wiring board according to claim 6, wherein the thermal expansion coefficient in the XY direction is set in a range of from 2 ppm to 15 ppm.

9. The printed wiring board according to claim 7, wherein the thermal expansion coefficient in the XY direction is set in a range of from 2 ppm to 15 ppm.

10. The printed wiring board according to claim 1, further comprising a buildup structure formed on the first conductive layer and the first surface of the core substrate.

11. The printed wiring board according to claim 1, further comprising:
a buildup structure formed on the first conductive layer and the first surface of the core substrate; and
an electronic component mounted on the buildup structure.

12. The printed wiring board according to claim 1, wherein the insulative base material further includes inorganic particles.

13. The printed wiring board according to claim 1, wherein the insulative base material further includes inorganic particles in an amount of from 20 wt. % to 60 wt. % the insulative base material.

14. The printed wiring board according to claim 1, wherein the insulative base material further includes silica particles or alumina particles.

15. The printed wiring board according to claim 1, wherein the reinforcing material of the insulative base material includes glass fibers or aramid fibers.

16. The printed wiring board according to claim 1, further comprising:
a first buildup structure formed on the first conductive layer and the first surface of the core substrate; and
a second buildup structure formed on the second conductive layer and the second surface of the core substrate.

17. The printed wiring board according to claim 1, wherein the reinforcing material of the insulative base material is a glass cloth.

18. The printed wiring board according to claim 1, wherein the insulative base material further includes inorganic particles, the inorganic particles are in an amount of from 10 wt. % to 50 wt. % in the insulative base material, and the reinforcing material of the insulative base material is an amount of from 30 wt. % to 70 wt. % in the insulative base material.

19. The printed wiring board according to claim 1, wherein the copper-plated film is an electrolytic copper-plated film formed in the penetrating hole such that the penetrating hole is filled and closed by the electrolytic copper-plated film.

20. The printed wiring board according to claim 1, wherein the resin of the insulative base material is an epoxy resin, and the reinforcing material of the insulative base material is a glass cloth comprising S-glass.
